(19) United States
(12) Patent Application Publication
(10) Pub. No.: US 2017/0245341 A1
(43) Pub. Date: Aug. 24, 2017

(54) LED DRIVING DEVICE WITH DETACHABLE SURGE PROTECTION

(71) Applicant: Samsung Electronics CO., Ltd., Suwon-si (KR)

(72) Inventor: Bong Jin Lee, Hwaseong-si (KR)

(21) Appl. No.: 15/259,534

(22) Filed: Sep. 8, 2016

(30) Foreign Application Priority Data
Feb. 22, 2016 (KR) 10-2016-0020533

(51) Int. Cl. H05B 33/08; H02H 7/12; H05B 37/02; H02H 9/04; H01L 33/50; H02H 7/125; H02H 1/04

(52) U.S. Cl. CPC H05B 33/0887; H02H 7/1252; H02H 7/1216; H02H 1/04; H02H 9/04; H01L 33/502; H05B 33/0845; H05B 33/0866; H05B 33/0815; H05B 37/0272; H01L 2933/0083; Y10S 977/774; Y10S 977/824; Y10S 977/818; Y10S 977/825; Y10S 977/95; B82Y 20/00

(57) ABSTRACT

An LED driving device includes a converter module configured to receive an input voltage and generate an output voltage for driving a plurality of LEDs. A surge protection module is electrically connected to the converter module. A case holds the converter module and the surge protection module, and provides electrical coupling therebetween.

### CROSS-REFERENCE TO RELATED APPLICATION

This application claims priority under 35 U.S.C. §119 from Korean Patent Application No. 10-2016-0020533 filed on Feb. 22, 2016 the disclosure of which is hereby incorporated by reference in its entirety.

### BACKGROUND

The present inventive concept relates to a light emitting diode (LED) device, and more specifically to an LED driver. including surge protection.

Light emitting devices increasing use LEDs, having various desirable attributes such as low power consumption, a high degree of brightness, and a long lifespan. Accordingly, the range of uses, as light sources, has steadily increased. Light emitting devices are used as light sources in various fields. Recently, research has been undertaken into the use of light emitting elements, as well as general light emitting devices such as backlight units and lighting devices, for a variety of applications.

### SUMMARY

In one aspect, the present inventive concepts are directed to light emitting diode (LED) driving device comprising a converter module configured to receive an input voltage and generating an output voltage for driving a plurality of LEDs. A surge protection module is electrically connected to the converter module. A case holds the converter module and the surge protection module therein, and provides electrical coupling therebetween.

In another aspect, the present inventive concepts are directed to a light emitting device comprising a driving unit including a converter module and a surge protection module connected to a single case. A light source unit includes a plurality of LEDs operated by an output power of the driving unit. The surge protection module is detachably connected to the case.

In another aspect, the present inventive concepts are directed to a light emitting device driver comprising a light emitting diode (LED) driver including a receptacle electrically connected to a mounting site. A surge protection module is detachably connected to the receptacle. The surge protection module includes at least one of a varistor, an arrestor, and a gas discharge tube (GDT) connected in series to form a shunt. The shunt is connected in parallel with an input pair receiving an input voltage. A converter module is connected to the mounting site. The converter module includes a rectifier connected between the input pair and a primary winding of a transformer, a low pass filter connected to the secondary winding of the transformer to generate an output voltage on an output pair, and a controller gating a path between the primary winding and a reference voltage to control the output voltage in response to a change in the input voltage and a current through the primary winding.

### BRIEF DESCRIPTION OF THE DRAWINGS

These and/or other aspects and advantages of the present general inventive concepts will become apparent and more readily appreciated from the following description of the embodiments, taken in conjunction with the accompanying drawings of which:

FIG. 1 is a plan view of a usage environment of a light emitting device according to an example embodiment of the present inventive concept.

FIG. 2 is a perspective view of a light emitting device according to an example embodiment of the present inventive concept.

FIG. 3A and FIG. 3B are perspective views of an LED driving device according to an example embodiment of the present inventive concept.

FIG. 4 is a schematic view of an LED driving device according to an example embodiment of the present inventive concept.

FIG. 5 to FIG. 7 are schematic views of an LED driving device circuit according to example embodiments of the present inventive concept.

FIG. 8 and FIG. 9 are schematic views of the operation of an LED driving device according to example embodiments of the present inventive concept.

FIG. 10A and FIG. 10B are schematic views of white light source modules employed in a light emitting device according to an example embodiment of the present inventive concept.

FIG. 11 is a graphical view of a CIE 1931 color space chromaticity diagram illustrating operations of white light source modules illustrated in FIG. 10A and FIG. 10B.

FIG. 12 is a schematic view of a wavelength conversion material used in a light emitting device package according to an example embodiment of the present inventive concept.

FIG. 13 is an exploded perspective view of a bar-type lamp applying an LED driving device according to an example embodiment of the present inventive concept.

FIG. 14 is an exploded perspective view of a bulb-type lamp applying an LED driving device according to an example embodiment of the present inventive concept.

### DETAILED DESCRIPTION

Reference will now be made in detail to the embodiments of the present general inventive concepts, examples of which are illustrated in the accompanying drawings, wherein like reference numerals refer to the like elements throughout. The embodiments are described below in order to explain the present general inventive concepts by referring to the figures.

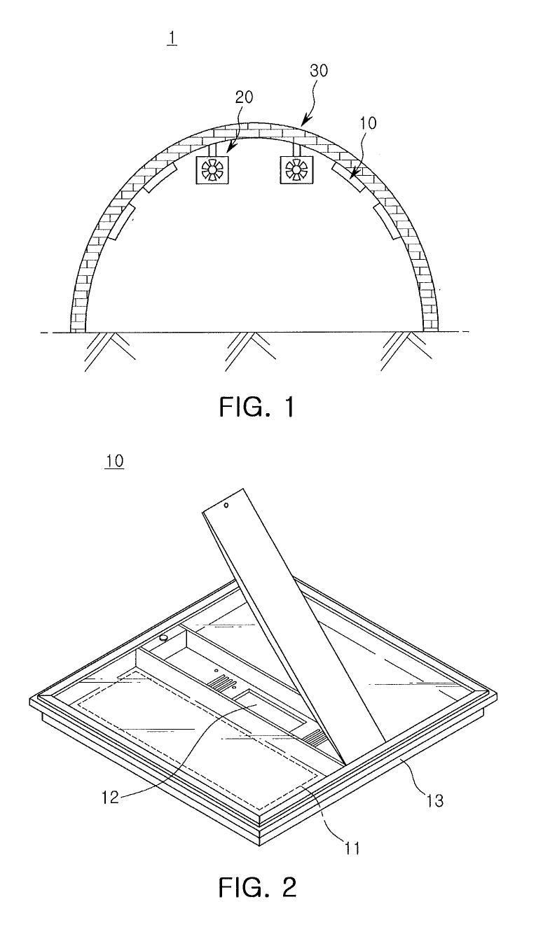

FIG. 1 is a plan view of a usage environment of a light emitting device according to an example embodiment of the present inventive concept. With reference to FIG. 1, an embodiment of a light emitting device 10 may be exposed to outdoor environments. The light emitting device 10 may be used as a lighting lamp inside a tunnel 30. A ventilation fan 20 may be installed inside the tunnel 30, in addition to the light emitting device 10. The fan 20 and the light emitting device 10 may receive power from same power source.

The fan 20 may include a rotating motor. When the motor included in the fan 20 repeatedly stops and restarts, back electromotive force (EMG) generated in the motor may influence the light emitting device 10. Thus, in an environment in which an inductive load such as a motor or the like is installed together with the light emitting device 10, a device capable of reducing an influence of back electromotive force may be included in the light emitting device 10.

In addition, the light emitting device 10 may include a device capable of protecting a circuit device, (e.g., an LED), from an electrical surge due to lightning strike, back EMF or other sources of current surging. For example, when the light emitting device 10 is installed to serve as a lighting device in the tunnel 30, as illustrated in FIG. 1, or to serve as a streetlight, or a safety lighting fixture, the light emitting device 10 may be outdoors and directly exposed to a lightning strike. Thus, a device for protecting a circuit device and an LED from electrical surge generated due to lightning strike may be included in the light emitting device 10.

To protect a circuit device and an LED from back electromotive force, or another source of electrical surge, the light emitting device 10 may include a surge protection module, for example, a surge protection device (SPD). In the light emitting device 10 according to an example embodiment, the surge protection module may be provided together with a converter module for driving an LED. Specifically, the surge protection module may be mounted in the case, which includes the converter module, while being detachable therefrom. Thus, when a lifespan of the surge protection module is reduced by back electromotive force or a surge voltage introduced thereto, only the surge protection module may need to be replaced, rather than replacing the entirety of the light emitting device 10, or the entirety of an LED driving device. Thus, the light emitting device 10 may be efficiently maintained but selectively replacing the surge device.

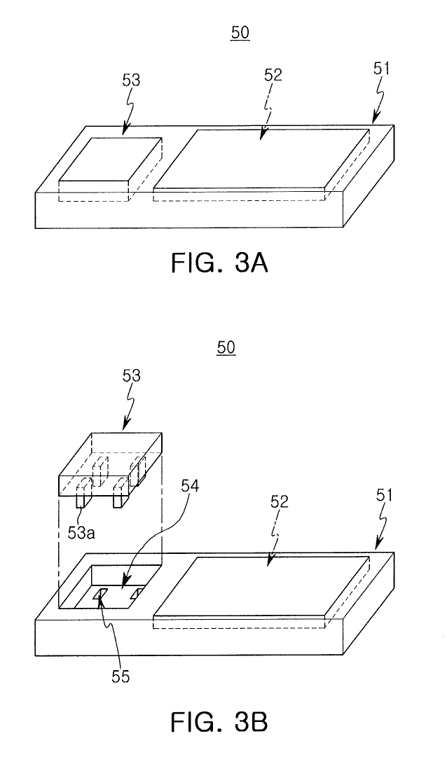

FIG. 2 is a perspective view of a light emitting device according to an example embodiment of the present inventive concept. With reference to FIG. 2, a light emitting device 10 according to an example embodiment may include a light source unit 11, a driving unit 12, and a housing 13. According to an example embodiment, the light source unit 11 may include a light emitting device array as a light source. The driving unit 12 may include a converter module supplying driving power to a light emitting device. In addition, the driving unit 12 may include a surge protection module for protecting the converter module and the light emitting device array from a surge voltage that may be introduced externally. The converter module and the surge protection module may be included in a single case, to be provided as a single module in the light emitting device 10.

The light source unit 11 may include a light emitting device array, formed to have a substantially planar shape. The driving unit 12 may be configured to supply power to the light source module 11. The housing 13 may have a receiving space in which the light source unit 11 and the driving unit 12 are accommodated. The light source module 11 may have a region having excellent light transmitting properties to emit light to a lateral surface of the housing 13.

As described above, the driving unit 12 may include a converter module and a surge protection module. The converter module and the surge protection module may be accommodated in a single case. The surge protection module may be accommodated in the case while being detachable therefrom. Thus, when a lifespan of the surge protection module is close to ending, a user or a manager of the light emitting device 10 may selectively replace only the surge protection module. Thus, since the entirety of the driving unit 12 does not need to be replaced due to a reduced lifespan of the surge protection module (relative to a lifespan of the driving unit 12), the light emitting device 10 may be maintained in an efficient and cost effective manner.

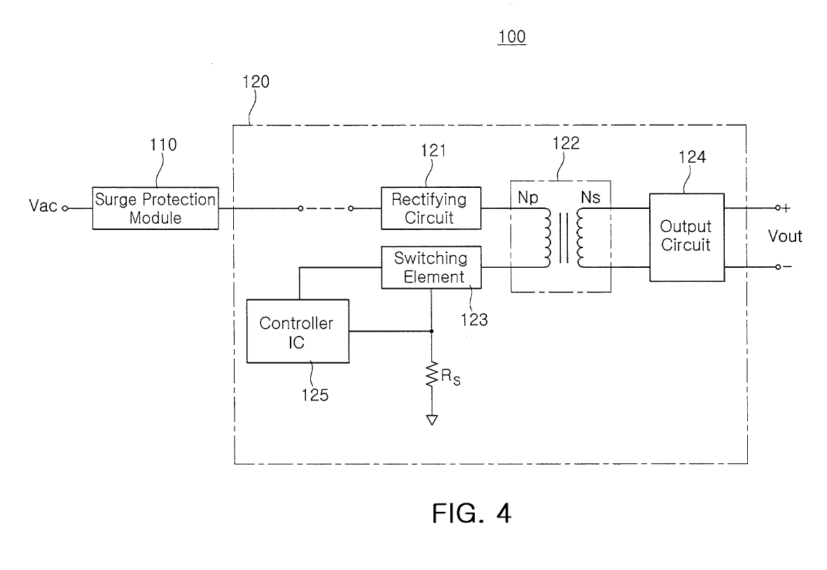

FIG. 3A and FIG. 3B are perspective views of an LED driving device according to an example embodiment of the present inventive concept. With reference to FIG. 3A and FIG. 3B, an LED driving device 50 may include a case 51, a converter module 52, and a surge protection module 53. The converter module 52 may be accommodated in the case, and may be configured to be integral with the case 51. The converter module 52 may include a plurality of circuit devices, (e.g. a controller IC), mounted on a printed circuit board.

The surge protection module 53 may be accommodated in the receiving space 54 of the case 51, and capable of being separated from the case 51. As illustrated in FIG. 3B, a plurality of connectors 55 are included in the receiving space 54 to electrically connect the surge protection module 53 to the converter module 52 through connections between the connectors 55 and the converter module 52 included in the case 51. The plurality of connectors 55 may be connected to terminals 53a provided on the surge protection module 53. For example, the surge protection module 53 may include two or more terminals 53a provided thereon. At least two of the terminals 53a may be connected to either a live terminal or a neutral terminal through which alternating current (AC) voltage is supplied. Other terminals may be connected to an input terminal of the converter module 52. In addition, the surge protection module 53 may be electrically located between the live terminal and a frame ground, and between the neutral terminal and the frame ground to protect the converter module 52.

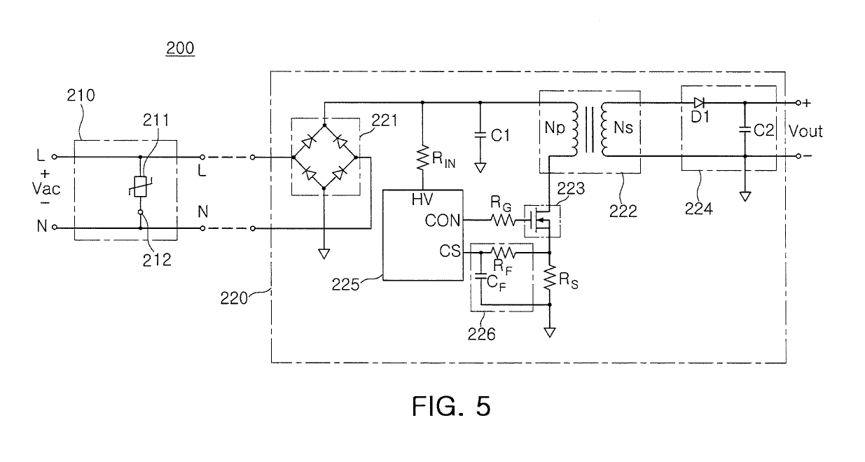

Hereinafter, the configurations of a driving unit 50 according to various example embodiments will be described with reference to FIG. 4 to FIG. 7.

FIG. 4 is a schematic view of an LED driving device according to an example embodiment of the present inventive concept. With reference to FIG. 4, an LED driving device 100 according to an example embodiment may include a surge protection module 110 and a converter module 120. The surge protection module 110 may be connected to an input terminal of the converter module 120. The surge protection module 110 may receive an alternating current (AC) voltage Vac. During a surge voltage on the AC power Vac, due to lightning strike, or back electromotive power, the surge protection module 110 may prevent the surge voltage from being introduced to the converter module 120.

The converter module 120 may include a rectifying circuit 121, a transformer 122 including a primary winding Np and a secondary winding Ns, a switching element 123 controlling a level of output voltage Vout (and hence power) from the converter module 120, an output circuit 124, and a controller IC 125. The rectifying circuit 121 may include a diode bridge circuit to rectify received AC voltage and to generate direct current (DC) voltage. The DC voltage generated by the rectifying circuit 121 may be transferred to the output circuit 124 through the transformer 122.

The switching element 123 may be connected in series to the primary winding Np of the transformer 122. Operations of the switching element 123 may be controlled by a controller integrated circuit (IC) 125. For example, the controller IC 125 may detect a voltage level across a current sensing resistor Rs connected to an output terminal of the switching element 123 to determine when to switch the switching element 123 on or off. The controller IC 125 may also control a duty ratio, or a switching frequency of the switching element 123 to control a magnitude of the output voltage Vout supplied to a plurality of LEDs.

For example, when the controller IC 125 turns the switching element 123 on, the output voltage Vout may be supplied by energy stored in the output circuit 124. When the controller IC 125 turns the switching element 123 off, energy accumulated in the primary winding Np of the transformer 122 may be transferred to the secondary winding Ns, and the output circuit 124 may output, as the output voltage Vout, the energy having been transferred to the secondary winding Ns of the transformer 122. Thus, a magnitude of the output voltage Vout (for a given current load, or an increased current supply for a fixed Vout) may be increased as a duty ratio or a switching frequency of the switching element 123 is increased. The output circuit 124 and the transformer 122 may be configured as a DC-DC converter circuit.

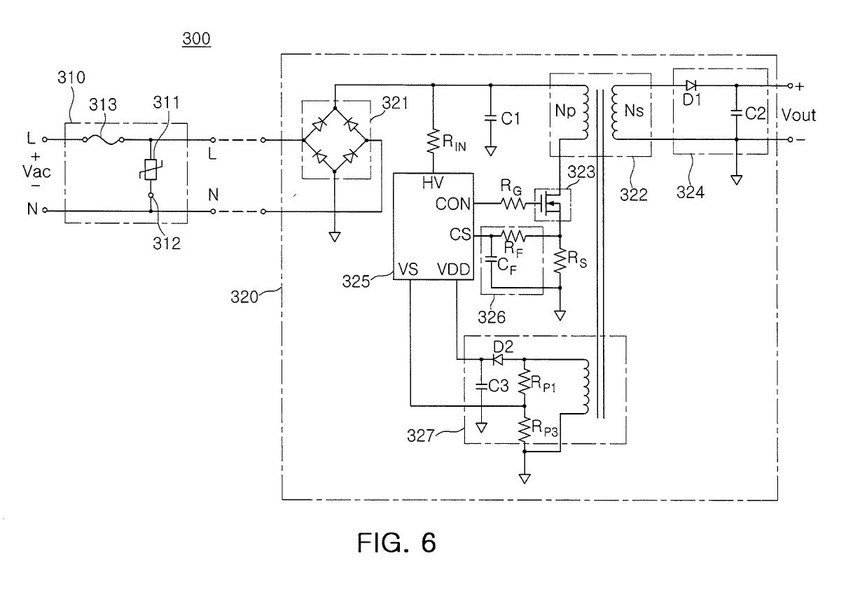

FIG. 5 to FIG. 7 are circuit diagrams of LED driving devices according to example embodiments of the present inventive concept. With reference to FIG. 5, an LED driving device 200 according to an example embodiment may include a surge protection module 210 and a converter module 220. The surge protection module 210 may include surge protection elements 211 and 212 connected in series between a live terminal L and a neutral terminal N supplying AC voltage Vac. A first surge protection element 211 may be a varistor (e.g., a variable resistor) as in the example embodiment of FIG. 5, and a second surge protection element 212 may be a gas discharge tube (GDT). In another embodiment, the surge protection module 210 may include only one surge protection element such as an arrestor, a varistor, or a GDT. In another embodiment, the surge protection module 210 may include three or more surge protection elements. An output terminal of the surge protection module 210 may be connected to an input terminal of the converter module 220.

The first surge protection element 211 may be implemented by a varistor. When a surge voltage is applied through the live terminal L, the varistor may send the surge voltage to the neutral terminal N, to prevent the surge voltage from being introduced to the converter module 220. The second surge protection element 212 may be implemented by a GDT. When a discharge of electricity occurs across the electrodes of the GDT due to a surge voltage supplied through the live terminal L, the surge voltage is shunted to the neutral terminal N through the GDT.

The AC power Vac from which the surge voltage has been removed by the surge protection module 210 may be applied to the rectifying circuit 221. The rectifying circuit 221 may include a diode bridge circuit to convert the AC voltage Vac to DC voltage. The DC voltage may be detected by a resistor R_{IN} connected to a high voltage (HV) pin of a controller IC 225. A capacitor C1 may be provided as a bypass capacitor to remove a high frequency noise component.

A primary winding Np of a transformer 222 may be connected to a semiconductor component, (e.g., a switching element 223 implemented by a field effect transistor (FET)). Operations of the switching element 223 may be controlled by a control signal transmitted from the controller IC 225 through a resistor R_{G}.

An output circuit 224 may be connected to a secondary winding Ns of the transformer 222, and may include a diode D1 and a capacitor C2. When the switching element 223 is turned on forming an electrical path between the primary winding Np and ground, energy may be stored in the transformer 222 by DC voltage output from the rectifying circuit 221, and the diode D1 may be biased in a reverse direction so that the DC voltage from the secondary winding Ns of the transformer 222 is not transferred to the output voltage Vout. Thus, the output voltage Vout from the converter module 220 may be supplied by energy stored in the capacitor C2 during this phase of operation. When the switching element 223 is turned off, the diode D1 may be biased in a forward direction, and the output voltage Vout may then be supplied by energy stored in the transformer 222.

The controller IC 225 may measure a voltage of a current sensing resistor Rs as a current detection voltage. A low pass filter 226 including a resistor R_{F} and a capacitor CF may be provided between the current sensing resistor Rs and the controller IC 225, to filter switching noise. The controller IC 225 may change a switching frequency or a duty ratio of the switching element 223 according to an increase or a decrease in a level of the current detection voltage to control a level of the output voltage Vout (and hence output power).

With reference to FIG. 6, an LED driving device 300 according to an example embodiment may include a surge protection module 310 and a converter module 320. The surge protection module 310 may include a varistor 311, a GDT 312, and a fuse 313. The varistor 311 and the GDT 312 may be connected to each other in series, but are not limited thereto.

The varistor 311 generally has a limited capability for absorbing surge voltages, and thus, a useful lifespan thereof has been determined. The varistor 311 of which a lifespan is close to ending is generally operated as an electrically-shorted circuit. When a surge voltage is re-introduced before replacing the varistor 311, the converter module 320 or an LED may not be efficiently protected. Because the varistor 311 and the GDT 312 are connected in series to each other, excellent response characteristics may be maintained in the varistor 311, simultaneously with solving a limited capacity problem.

In addition, the fuse 313 may be connected between the live terminal L and the varistor 311 in the example embodiment of FIG. 5. When a surge voltage is applied to the varistor 311, a thermal runaway phenomenon in which a temperature of the varistor 311 is rapidly increased may occur. In an example embodiment, by connecting the fuse 313 to the varistor 311, the converter module 320 may be protected from a surge voltage in a case in which a thermal runaway phenomenon occurs in the varistor 311 or a lifespan of the varistor 311 is close to ending while remaining as an electrically-shorted circuit.

The converter module 320 may be similar the embodiment of a convertor module 220 of FIG. 5. The converter module 320 may include a rectifying circuit 321, a transformer 322, a switching element 323, an output circuit 324, and a controller IC 325. The controller IC 325 may detect a signal output from the rectifying circuit 321 through an input resistor R_{IN}, received through an HV pin, and may detect a voltage of a current sensing resistor Rs connected to the switching element 323 through a CS pin. The voltage detected through the CS pin may be a current detection voltage. The current detected voltage at the CS pin is represented by a voltage being proportional a current through Rs. The controller IC 325 may receive a current necessary for initial driving through the HV pin, and may detect a level of current flowing in the switching element 323 through the CS pin.

In addition, the converter module 320 illustrated in FIG. 6 may include an auxiliary wiring 327. The power required to operate the controller IC 325 may be supplied to a VDD pin by the auxiliary wiring 327. The controller IC 325 may detect a voltage level of the auxiliary wiring 327 through a VS pin, to calculate a level of output from the secondary winding Ns of the transformer 322. The controller IC 325 may generate a control signal, based on an input value provided through the CS pin and the VS pin, and may supply the control signal to a gate terminal of the switching element 323 through a CON pin.

With reference to FIG. 7, an LED driving device 400 according to an example embodiment may include a surge protection module 410 and a converter module 420. The surge protection module 410 may include a plurality of varistors 411 and 412, and a plurality of switches 413 and 414.

The plurality of switches 413 and 414 may be connected in series to the plurality of varistors 411 and 412, respectively. With reference to FIG. 7, a first switch 413 is turned on to allow a first varistor 411 to be connected between a live terminal L and a neutral terminal N, and a second switch 414 is turned off to allow a second varistor 412 to be disconnected from the live terminal L. When an external surge voltage is supplied to the live terminal L, the surge voltage may be shunted to the neutral terminal N by the first varistor 411.

As described above, the capability of the varistor 411 to remove a surge voltage may be limited. In the example embodiment with reference to FIG. 7, the plurality of varistors 411 and 413 may be disposed between the live terminal L and the neutral terminal N, wherein one of the plurality of varistors 411 and 413 may be selectively connected to the live terminal L using the respective switches 412 and 414. Thus, the first varistor 411 may first be used, and when a lifespan of the first varistor 411 is close to ending and the first varistor 411 needs to be replaced, the second varistor 412 may be connected, thereby providing a relatively long exchange lifespan of the surge protection module 410. The first varistor 411 and the second varistor 412 are illustrated as being included in a single surge protection module 410, but may be included in two surge protection modules 410 connected in series.

The converter module 420 may include a rectifying circuit 421, a PFC converter 422, a DC-DC converter 423, a controller IC 425, and the like. The PFC converter 422 may include a boost converter circuit, and may include an inductor L1, a diode D1, a capacitor C1, and a switching element Q1. The DC-DC converter 423 connected to the PFC converter 422 in series may include a buck converter circuit, and may include an inductor L2, a diode D2, a capacitor C2, and a switching element Q2. Operations of the switching elements Q1 and Q2 included in the PFC converter 422 and the DC-DC converter 423, respectively, may be controlled by the controller IC 425, and an output of the output power Vout may be determined by operations of the switching elements Q1 and Q2.

In the LED driving devices 200, 300 and 400 according to the example embodiments with reference to FIG. 5 to FIG. 7, portions of the configurations may be interchanged with each other and used. For example, the LED driving device 200 according to the example embodiment shown in FIG. 5 may include a plurality of varistors 411 and 412 in the surge protection module 210 as shown in FIG. 7, or may include a fuse 313 as shown in FIG. 6. Conversely, the LED driving devices 200, 300 and 400 of FIG. 5 to FIG. 7, may use any one of the converter modules 220, 320 and 420 according to other example embodiments. Also, the surge protection module 210, 310, or 410 may include only one surge protection element.

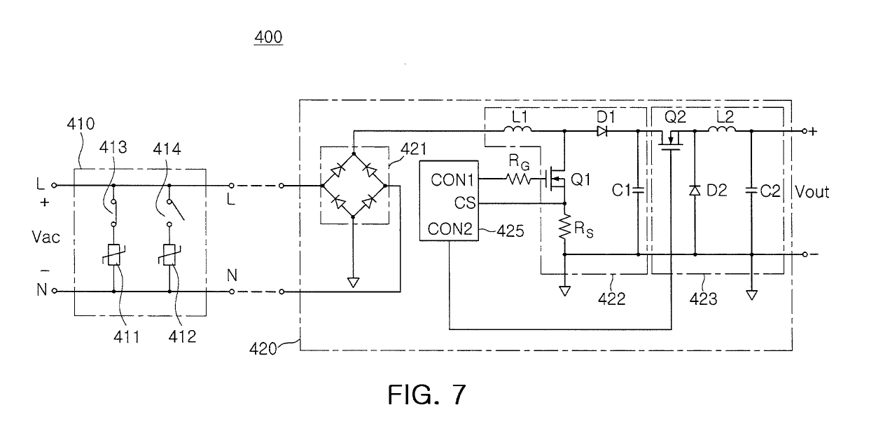

According to an example embodiment, the surge protection modules 210, 310 or 410 may further include a display unit informing a user or a manager of a light emitting device of an estimated remaining lifespan, or an operating state of the surge protection module. The display unit may be exposed externally from the case in which the surge protection module and the converter module are accommodated. Hereinafter, operations of an LED driving device will be described with reference to FIG. 8 and FIG. 9.

FIG. 8 and FIG. 9 are schematic views of the operation of an LED driving device according to example embodiments of the present inventive concept. With reference to FIG. 8, an LED driving device 500 according to an example embodiment may include a surge protection module 510 and a converter module 520 accommodated in a case 530. In another embodiment, the surge protection module 510 may be accommodated in the case 530 such that at least a portion of the surge protection module 510 may be exposed externally from the case 530. The surge protection module 510 may include a first display unit 511 for displaying whether the surge protection module is normally operated, and a second display unit 512 for displaying an estimated remaining lifespan of the surge protection module.

In an example embodiment, the first display unit 511 may display information with respect to whether the surge protection module 510 is normally operated, for a user or a manager of the lighting device by selectively turning the light either on or off. In an example embodiment, while the surge protection module 510 is normally operated, the first display unit 511 may not light up, and in a case in which a lifespan of the surge protection module 510 is close to ending or a failure has occurred therein, the first display unit 511 may light up.

The second display unit 512 may be provided to display information regarding an estimated remaining lifespan of the surge protection module 510. To measure an estimated remaining lifespan of the surge protection module 510, the surge protection module 510 may include a unit for sensing a leakage current flowing in a surge protection device such as a varistor. The surge protection module 510 determines if a level of a leakage current flowing in a ground line connected to a surge protection device has increased to indicated that an estimated remaining lifespan of the surge protection device is reduced, and represents the determined result through the second display unit 512. In an example embodiment, the second display unit 512 may include a light emitting device of which the degree of flickering (e.g., through a/c modulation of an LED status light), or a color of light is changed according to the estimated remaining lifespan of the surge protection device.

With reference to FIG. 9, an LED driving device 600 according to an example embodiment may include a surge protection module 610 and a converter module 620 accommodated in a case 630. Similar to the embodiment 500 of FIG. 8, at least a portion of the surge protection module 610 may be exposed externally from the case 630, and may include a first display unit 611 and a second display unit 612.

In an example embodiment, the first display unit 611 may be provided to display information regarding an estimated remaining lifespan of the surge protection module 610. As described above with reference to the example embodiment of FIG. 8, an estimated remaining lifespan of the surge protection device may be determined from a level of leakage current flowing in a ground terminal connected to the surge protection device included in the surge protection module 610. By displaying information regarding an estimated remaining lifespan of the surge protection device through the first display unit 611, a user or a manager may be notified as to whether the surge protection module 610 needs to be replaced.

The second display unit 612 may be provided to display a magnitude of a surge voltage introduced to the surge protection module 610. A magnitude of the surge voltage displayed on the second display unit 612 may be a maximum value or an average value of the surge voltage having been introduced to the surge protection module 610. A user or a manager of the light emitting device may determine whether to replace the surge protection module 610 with a surge protection module 610 of a relatively higher capacity by referring to a level of the surge voltage displayed on the second display unit 612.

To display a level of the surge voltage through the second display unit 612, the surge protection module 610 may detect a level of voltage of at least one node of a circuit included in the converter module 620. Referring to the circuit according to the example embodiment of FIG. 5 by way of example, the surge protection module 610 may detect a level of voltage in at least one of an input terminal and an output terminal of the rectifying circuit 221, and a node between the current sensing resistor Rs and the switching element 223, to calculate a level of the surge voltage. For example, the primary winding Np of the transformer 222 is an open circuit during a step function response, hence the voltage difference across the primary winding Np is a measure of the voltage surge applied to the LED driving device 200.

LED driving devices according to various example embodiments may include a converter module and a surge protection module accommodated in a single case. The surge protection module may be accommodated in the case while being detachable therefrom. Only the surge protection module need be replaced before a lifespan of the converter module supplying driving power to an LED ends where the lifespan is limited by the surge protection module. Accordingly, the LED driving device may thus be efficiently maintained. In addition, information regarding an operating state and an estimated remaining lifespan of the surge protection module, and a surge voltage introduced to the surge protection module, may be provided through a display unit disposed in the surge protection module. Thus, information as to whether the surge protection module needs to be replaced based on an estimated remaining lifespan of the surge protection module is provided.

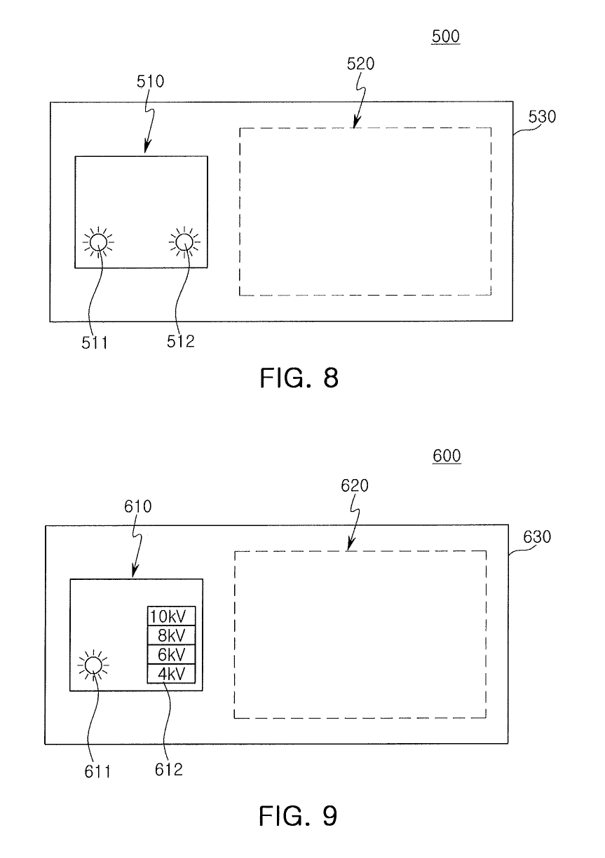

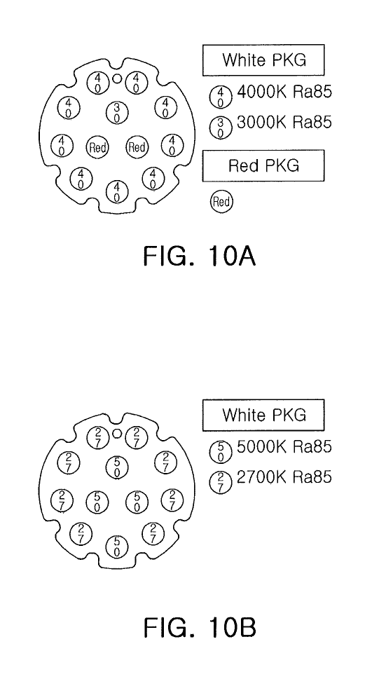

FIG. 10A and FIG. 10B are schematic views of white light source modules employed in a light emitting device according to an example embodiment of the present inventive concept. FIG. 11 is a graphical view of a CIE 1931 color space chromaticity diagram illustrating operations of the white light source modules illustrated in FIG. 10A and FIG. 10B. The white light source modules illustrated in FIG. 10A and FIG. 10B may respectively include a plurality of light emitting device packages mounted on a circuit board. The plurality of light emitting device packages mounted on a single white light source module may be configured to have the same wavelength, or may also be configured to have different wavelengths.

With reference to FIG. 10A, a white light source module may be configured by combining white light emitting device packages ‘40’ and ‘30’ having color temperatures of 4000K and 3000K, respectively, and red light emitting device packages ‘Red’. The white light source module may provide white light having a color temperature adjustable within a range of 3000K to 4000K and having a color rendering index Ra within a range of 95 to 100.

In another example embodiment, a white light source module may be configured to have only white light emitting device packages. In this case, a portion of the white light emitting device packages may have white light having a different color temperature. For example, as illustrated in FIG. 10B, white light of which a color temperature may be adjusted to be within a range of 2700K to 5000K and of which a color rendering index Ra is within a range of 85 to 99 may be provided by combining a white light emitting device package ‘27’ having a color temperature of 2700K and a white light emitting device package ‘50’ having a color temperature of 5000K. Here, the number of light emitting device packages having a specific color temperature may be mainly changed depending on a preset value of a basic color temperature. For example, when a lighting device has a preset basic value of color temperature of 4000K, the number of packages thereof corresponding to a color temperature of 4000K may be more than the number of packages having a color temperature corresponding to 3000K or the number of red light emitting device packages.

Accordingly, the heterogeneous light emitting device packages may be configured to include a light emitting device provided by combining a yellow, green, red, or orange phosphor with a blue light emitting device to emit white light and at least one of violet, blue, green, red, or infrared light emitting devices, to adjust a color temperature and a color rendering index (CRI) of white light. The white light source module described above may be employed as a light source in various types of lighting devices.

In a single light emitting device package, light having a required color may be determined depending on a wavelength of light from a light emitting diode (LED) chip, a light emitting device, a phosphor type, and a combination ratio of phosphors. In this case, when the light is white light, a color temperature and a color rendering index thereof may be controlled.

For example, when the LED chip emits blue light, a light emitting device package including at least one of yellow, green, and red phosphors may emit white light having various color temperatures according to a phosphor combination ratio. In another embodiment, a light emitting device package, in which a green or red phosphor is applied to a blue LED chip, may emit green or red light. By combining the light emitting device package emitting white light and the light emitting device package emitting green or red light, a color temperature and a color rendering index (CRI) of white light may be controlled. In addition, a light emitting device package may also be configured to include at least one of light emitting devices emitting violet light, blue light, green light, red light, and infrared light.

The CRI of the lighting device may be adjusted from a level of a sodium-vapor lamp to a level of sunlight, and various types of white light having a color temperature of around 1500K to around 20000K may be generated. In addition, a lighting color may be adjusted to be appropriate for an ambient atmosphere or for viewer mood by generating violet, blue, green, red, orange visible light or infrared light as needed. Further, the lighting device may also emit light within a special wavelength band, capable of promoting plant growth.

White light obtained by combining yellow, green, red phosphors and/or green and red light emitting devices with a blue light emitting device may have two or more peak wavelengths, and coordinates (x,y) thereof in the CIE 1931 color space chromaticity diagram illustrated in FIG. 11 may be located on line segments (0.4476,0.4074), (0.3484,0.3516), (0.3101,0.3162), (0.3128,0.3292), and (0.3333,0.3333) connected to one another. Alternatively, the coordinates (x,y) may be located in a region surrounded by the line segments and blackbody radiation spectrum. A color temperature of white light may be within a range of 1500K to 20000K. In FIG. 11, white light in the vicinity of a point E (0.3333,0.3333) below the blackbody radiation spectrum may be in a state in which light of a yellow-based component becomes relatively weak. This white light may be used as an illumination light source of a region in which a relatively bright or refreshing mood may be provided to the naked eye. Thus, a lighting device product using white light in the vicinity of the point E (0.3333,0.3333) below the blackbody radiation spectrum may be effective for use in retail spaces in which groceries, clothing, and the like are for sale.

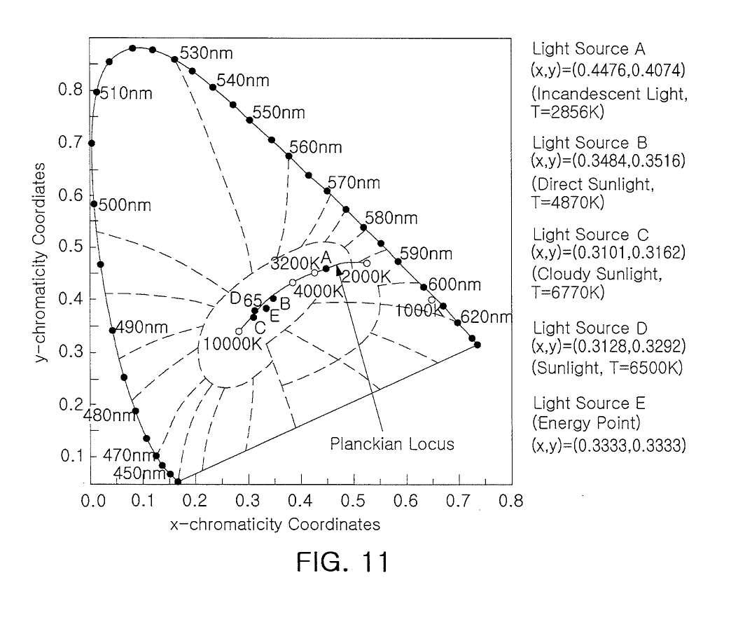

FIG. 12 is a schematic view of a wavelength conversion material that may be applied to a light emitting device package according to an example embodiment of the present inventive concept. The wavelength conversion material may be a material for converting a wavelength of light emitted from a light emitting device. The wavelength conversion material may include various materials such as a phosphor and/or a quantum dot.

In an example embodiment, phosphors applied to the wavelength conversion material may be represented by the following empirical formula and have colors as listed below.

Oxide-based Phosphor: Yellow and green Y₃Al₅O₁₂:Ce, Tb₃Al₅O₁₂:Ce, Lu₃Al₅O₁₂: Ce

Silicate-based Phosphor: Yellow and green (Ba,Sr)₂SiO₄:Eu, Yellow and yellowish-orange (Ba,Sr)₃SiO₅:Ce

Nitride-based Phosphor: Green β-SiAlON:Eu, Yellow La₃Si₆N₁₁:Ce, Yellowish-orange α-SiAlON:Eu, Red CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y} (0.5≦x≦3, 0<z<0.3, 0<y≦4)—Formula (1) (Here, Ln may be at least one element selected from a group consisting of group IIIc elements and rare-earth elements, and M may be at least one element selected from a group consisting of Calcium (Ca), Barium (Ba), Strontium (Sr), and Magnesium (Mg).

Fluoride-based Phosphor: KSF-based red K₂SiF₆:Mn₄⁺, K₂TiF₆:Mn₄⁺, NaYF₄:Mn₄⁺, NaGdF₄:Mn₄⁺, K₃SiF₇:Mn⁴⁺

A composition of phosphor should approximately coincide with stoichiometry, and respective elements may be substituted with other elements in a group of the periodic table of elements in which an element corresponding thereto is included. For example, Sr may be substituted with Ba, Ca, Mg, or the like, of an alkaline earth group II, and Y may be substituted with Lanthanum-Based Terbium (Tb), Lutetium (Lu), Scandium (Sc), Gadolinium (Gd), or the like. In addition, Eu an activator, may be substituted with Cerium (Ce), Tb, Praseodymium (Pr), Erbium (Er), or Ytterbium (Yb), according to a required energy level. In addition, an activator may be used alone, or a sub-activator or the like, for modification of characteristics thereof, may additionally be used.

Specifically, in the case of a fluoride-based red phosphor, in order to improve reliability thereof at a relatively high temperature/high humidity, a phosphor may be coated with a Fluoride not containing Manganese (Mn), or a Phosphor surface or a Fluoride-coated surface of Phosphor coated with a Fluoride not containing Mn may further be coated with an organic material. In the case of the Fluoride-based red phosphor as described above, a full width at half maximum of 40 nm or less may be obtained in a manner different from the case of other Phosphors, and thus, the Fluoride-based red phosphor may be used in high-resolution TV sets such as UHD TVs.

The following table 1 illustrates Phosphor types in light emitting device packages using a blue LED chip having a dominant wavelength in a range of 440 nm to 460 nm or a UV LED chip having a dominant wavelength in a range of 380 nm to 440 nm, which may be applied to respective fields of application.

TABLE 1

| USE | PHOSPHOR | USE | PHOSPHOR |
|---|---|---|---|
| LED TV BLU | β-SiAlON:Eu2+ | Side View | Lu₃Al₅O₁₂:Ce3+ |
| | (Ca,Sr)AlSiN₃:Eu2+ | (Mobile Note PC) | Ca-α-SiAlON:Eu2+ |
| | La₃Si₆N₁₁:Ce3+ | | La₃Si₆N₁₁:Ce3+ |
| | K₂SiF₆:Mn4+ | | (Ca,Sr)AlSiN₃:Eu2+ |
| | SrLiAl3N4:Eu | | Y₃Al₅O₁₂:Ce3+ |
| | Ln₄₋ₓ(Eu_{z}M_{1-z})ₓSi_{12-y}Al_{y}O_{3+x+y}N_{18-x-y} | | (Sr,Ba,Ca,Mg)2SiO4:Eu2+ |
| | (0.5 ≦ x ≦ 3, 0 < z < 0.3, 0 < y ≦ 4) | | K₂SiF₆:Mn4+ |
| | K2TiF6:Mn4+ | | SrLiAl3N4:Eu |
| | NaYF4:Mn4+ | | Ln₄₋ₓ(Eu_{z}M_{1-z})ₓSi_{12-y}Al_{y}O_{3+x+y}N_{18-x-y} |
| | NaGdF4:Mn4+ | | (0.5 ≦ x ≦ 3, 0 < z < 0.3, 0 < y ≦ 4) |
| | | | K2TiF6:Mn4+ |
| | | | NaYF4:Mn4+ |
| | | | NaGdF4:Mn4+ |
| | | VEHICLE | |
| ILLUMINATION | | HEADLIGHTS | |
| | Lu₃Al₅O₁₂:Ce3+ | (Head Lamp, etc.) | Lu₃Al₅O₁₂:Ce3+ |
| | Ca-α-SiAlON:Eu2+ | | Ca-α-SiAlON:Eu2+ |
| | La₃Si₆N₁₁:Ce3+ | | La₃Si₆N₁₁:Ce3+ |
| | (Ca,Sr)AlSiN₃:Eu2+ | | (Ca,Sr)AlSiN₃:Eu2+ |
| | Y₃Al₅O₁₂:Ce3+ | | Y₃Al₅O₁₂:Ce3+ |
| | K₂SiF₆:Mn4+ | | K₂SiF₆:Mn4+ |
| | SrLiAl3N4:Eu | | SrLiAl3N4:Eu |
| | Ln₄₋ₓ(Eu_{z}M_{1-z})ₓSi_{12-y}Al_{y}O_{3+x+y}N_{18-x-y} | | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4) | | (0.5 ≦ x ≦ 3, 0 < z < 0.3, 0 < y ≦ 4) |
| | K2TiF6:Mn4+ | | K2TiF6:Mn4+ |
| | NaYF4:Mn4+ | | NaYF4:Mn4+ |
| | NaGdF4:Mn4+ | | NaGdF4:Mn4+ |

Conversely, the wavelength conversion material may include a quantum dot (QD) provided to be used as a phosphor substitute or to be mixed with a phosphor.

FIG. 12 is a view illustrating a cross-sectional structure of a quantum dot. The quantum dot (QD) may have a core-shell structure using a group III-V or group II-VI compound semiconductor. For example, the quantum dot may have a core such as a structure of CdSe, InP, and a shell such as a structure of ZnS, ZnSe. Further, the QD may include a ligand for stabilization of the core and the shell. For example, the core may have a diameter in a range of 1 nm to 30 nm, in detail, 3 nm to 10 nm in an example. The shell may have a thickness in a range of 0.1 nm to 20 nm, in detail, 0.5 nm to 2 nm in one example.

The quantum dot may implement various colors depending on the size thereof. In detail, in a case in which the quantum dot is used as a phosphor substitute, the quantum dot may be used as a red or green Phosphor. In the case of using the quantum dot, a narrow full width at half maximum of, for example, about 35 nm may be obtained.

For example, the wavelength conversion material may be provided in a form being contained in an encapsulation material or in a scheme in which it is manufactured as a film in advance to be attached to a surface of an optical device such as an LED chip or a light guide plate. When using a wavelength conversion material that is manufactured as a film in advance, the wavelength conversion material having a uniform thickness may be easily implemented.

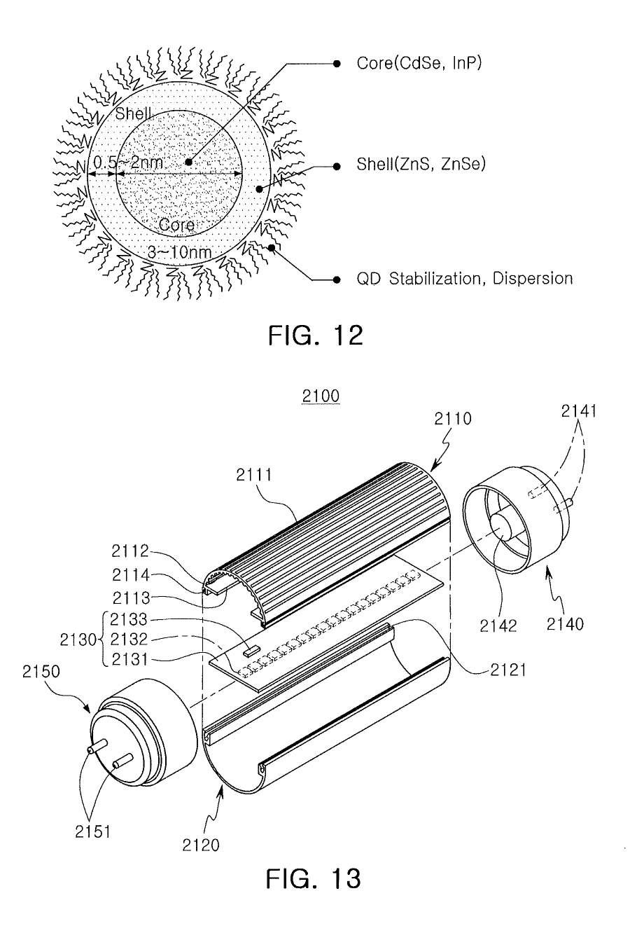

FIG. 13 is a schematic exploded perspective view of a bar-type lamp, a lighting device, to which an LED driving device according to an example embodiment may be applied. Specifically, a lighting device 2100 may include a heat sink member 2110, a cover 2120, a light source module 2130, a first socket 2140, and a second socket 2150. A plurality of heat radiating fins 2111 and 2112 having a concave-convex form may be formed on an inner surface or/and an external surface of the heat sink member 2110, and the heat radiating fins 2111 and 2112 may be designed to have various forms and intervals therebetween. A support portion 2113 having a protrusion form may be formed on an inner side of the heat sink member 2110. The light source module 2130 may be fixed to the support portion 2113. A stop protrusion 2114 may be formed on two ends of the heat sink member 2110.

A stop groove 2121 may be formed in the cover 2120. The stop groove 2121 may be coupled to the stop protrusion 2114 of the heat sink member 2110 in a hook coupling structure. Positions in which the stop groove 2121 and the stop protrusion 2114 are formed may also be interchanged.

The light source module 2130 may include a light emitting device array. The light source module 2130 may include a printed circuit board 2131, a light source 2132, and a controller 2330. As described above, the controller 2133 may store driving information for the light source 2132 therein, Circuit wires for operating the light source 2132 may be disposed in the printed circuit board 2131. In addition, the printed circuit board 2131 may also include constituent elements for operating the light source 2132. The controller 2133 may detect a level of power transferred through the first and second sockets 2140 and 2150 and compare the detected power level with a predetermined reference power level range, to determine whether a defeat is present in a plurality of LEDs included in the light source 2132.

The first and second sockets 2140 and 2150 respectively may be provided as a pair of sockets, and may have a structure in which they are coupled to two ends of a cylindrical cover unit configured of the heat sink member 2110 and the cover 2120. For example, the first socket 2140 may include electrode terminals 2141 and a power supply device 2142, and the second socket 2150 may include dummy terminals 2151 disposed thereon. In addition, an optical sensor and/or a communications module may be disposed inside one of the first socket 2140 or the second socket 2150. For example, the optical sensor and/or the communications module may be embedded in the second socket 2150 on which the dummy terminals 2151 are disposed. In another example, an optical sensor and/or a communications module may be embedded in the first socket 2140 on which the electrode terminals 2141 are disposed.

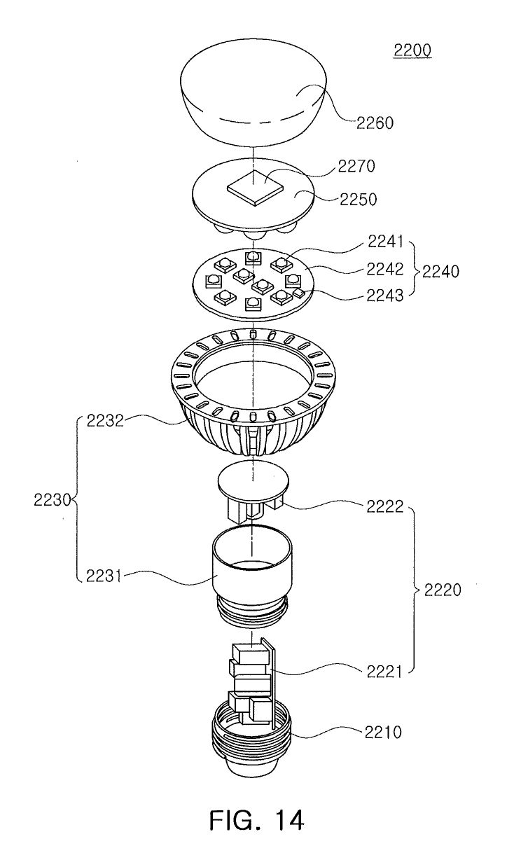

FIG. 14 is a exploded perspective view of a bulb-type lamp applying an LED driving device according to an example embodiment of the present inventive concept. With reference to FIG. 14, a lighting device 2200 may include a bulb base 2210, a driving circuit 2220, a heat sink unit 2230, a light source 2240, a communications module 2270, and an optical unit 2260. According to an example embodiment of the present inventive concept, the light source 2240 may include a light emitting device array. The driving circuit 2220 may include a rectifying circuit, a DC-DC converter or an AC direct-coupled driving circuit. A reflective plate 2250 may be provided above the light source 2240. The reflective plate 2250 may allow for uniform spreading of light from the light source 2240 sideways and backwards to reduce a glare effect of light.

The bulb base 2210 may be configured to allow the lighting device to be substituted with an existing lighting device. Power supplied to the lighting device 2200 may be applied through the bulb base 2210 thereto. As illustrated in FIG. 14, the driving circuit 2220 may include a first circuit unit 2221 and a second circuit unit 2222 that are separated from or coupled to each other. The driving circuit 2220 may include a surge protection module, and the surge protection module may be included in the same module as a module of one of the first and second circuit units 2221 and 2222.

The heat sink unit 2230 may include an internal heat sink portion 2231 and an external heat sink portion 2232. The internal heat sink portion 2231 may be directly connected to the light source 2240 and/or the driving circuit 2220, by which heat may be transferred to the external heat sink portion 2232. The optical unit 2260 may include an internal optical portion, (not shown), and an external optical portion, (not shown), and may be configured such that light emitted from the light source 2240 may be uniformly dispersed.

The light source 2240 may receive power from the driving circuit 2220 to emit light to the optical unit 2260. The light source 2240 may include one or more light emitting devices 2241, a circuit board 2242, and a controller 2243. The controller 2243 may store driving information for the light emitting devices 2241 therein. The controller 2243 may include at least one of a power detection circuit, or a control circuit according to an example embodiment. The controller 2243 may detect a level of power supplied through the bulb base 2210 to determine whether a defect is present in a plurality of LEDs included in the light source 2240. The controller 2243 may also be included in the first and second circuit units 2221 and 2222, other than in the light source 2240.

The communications module 2270 may be mounted on an upper portion of the reflective plate 2250, and home-network communications may be implemented through the communications module 2270. For example, the communications module 2270 may be a wireless communications module using ZigBee®, Wi-Fi, or Li-Fi, and may control illumination of lighting devices installed indoors or outdoors, such as switching on/off, adjustment of brightness, or the like, through a smartphone or a wireless controller. In addition, electronic products in the home or outdoors and automobile systems, such as TV sets, refrigerators, air conditioners, door locks, automobiles, or the like, may be controlled using a Li-Fi communications module using a visible light wavelength of a lighting device installed indoors or outdoors.

The reflective plate 2250 and the communications module 2270 may be covered by the optical unit 2260. The communications module 2270 may also be implemented as a single integrated circuit, with the controller 2243. In addition, the controller 2243 may be provided as a separate module from the light source 2240.

As set forth above, in an LED driving device and a light emitting device according to example embodiments, a converter module for driving an LED and a surge protection module for blocking introduction of a surge voltage may be accommodated together in a single case. Specifically, the surge protection module may be accommodated in the case to be easily separated therefrom. Thus, when a lifespan of the surge protection module is close to ending (and unable to withstand an additional surge voltage), or the surge protection module is required to be replaced with a surge protection module of a different capacity, only the surge protection module need be replaced, rather than replacing the entirety of the LED driving device. Thus, maintenance costs may be reduced.

Although a few embodiments of the present general inventive concepts have been shown and described, it will be appreciated by those skilled in the art that changes may be made in these embodiments without departing from the principles and spirit of the general inventive concepts, the scope of which is defined in the appended claims and their equivalents.

What is claimed is:

1. A light emitting diode (LED) driving device comprising:
a converter module configured to receive an input voltage and generate an output voltage for driving a plurality of LEDs;
a surge protection module electrically connected to the converter module; and
a case holding the converter module and the surge protection module, and providing electrical coupling therebetween.

2. The LED driving device of claim 1 wherein the converter module comprises:
a transformer having a primary winding and a secondary winding;
a rectifying circuit configured to rectify the input voltage and provide rectified input voltage to the primary winding;
a switching element connected in series with the primary winding;
a controller integrated circuit (IC) configured to control the switching element; and
an output circuit connected to the secondary winding to supply the output voltage to the plurality of LEDs.

3. The LED driving device of claim 2, wherein the surge protection module comprises at least one of a varistor, an arrestor, and a gas discharge tube (GDT) device connected between a pair of input terminals of the rectifying circuit including a live terminal and a neutral terminal, wherein the input voltage is supplied across the live terminal and the neutral terminal.

4. The LED driving device of claim 3, wherein the surge protection module includes two or more of the varistor, the arrestor, and the GDT device connected in series.

5. The LED driving device of claim 2, wherein the converter module further comprises a fuse connected between a live terminal receiving the input voltage and the rectifying circuit.

6. The LED driving device of claim 2, wherein the surge protection module detects a voltage level of at least one of an input terminal of the rectifying circuit, an output terminal of the rectifying circuit, and an output terminal of the switching element, to measure a level of a surge voltage applied to the input terminal.

7. The LED driving device of claim 6, wherein the surge protection module outputs at least one of a maximum value and an average value of the surge voltage.

8. The LED driving device of claim 1, wherein the surge protection module is detachably connected to an accommodation space in the case.

9. The LED driving device of claim 1, wherein the surge protection module is connected to the converter module by a connector in an accommodation space in the case, the connector electrically connected to the converter module.

10. The LED driving device of claim 1, wherein the surge protection module comprises a plurality of surge protection circuits and a switching unit connecting at least one of the plurality of surge protection circuits to an input terminal of the converter module.

11. The LED driving device of claim 10, wherein the switching unit connects a first surge protection circuit of the plurality of surge protection circuits to the input terminal of the converter module.

12. The LED driving device of claim 11, wherein the switching unit connects a second surge protection circuit to the input terminal of the converter module when a lifespan of the first surge protection circuit is close to ending.

13. A light emitting device comprising:
a driving unit including a converter module and a surge protection module connected to a single case; and
a light source unit including a plurality of LEDs operated by an output power of the driving unit,
wherein the surge protection module is detachably connected to the case.

14. The light emitting device of claim 13, wherein the surge protection module outputs information including at least one of an estimated remaining lifespan of the surge protection module and a level of a surge voltage measured by the converter module.

15. The light emitting device of claim 13, wherein the surge protection module comprises at least one of a varistor, an arrestor, and a gas discharge tube (GDT) device connected between a pair of input terminals configured to receive an input power, the pair of input terminals including a live terminal and a neutral terminal.

16. A light emitting device driver comprising:
a light emitting diode (LED) driver including a receptacle electrically connected to a mounting site;
a surge protection module detachably connected to the receptacle, the surge protection module including at least one of a varistor, an arrestor, and a gas discharge tube (GDT) connected in series to form a shunt, the shunt connected in parallel with an input pair receiving an input voltage; and
a converter module connected to the mounting site, the converter module including a rectifier connected between the input pair and a primary winding of a transformer, a low pass filter connected to the secondary winding of the transformer to generate an output voltage on an output pair, and a controller gating a path between the primary winding and a reference voltage to control the output voltage in response to a change in the input voltage and a current through the primary winding.

17. The device of claim 16 wherein the surge protection module includes a plurality of switchable varistors connected in parallel between the input pair, each switchable varistor configured to be selectively enabled.

18. The device of claim 16 wherein the controller gates the path between the primary winding and the reference voltage in response to a change in the input voltage, the current through the primary winding, and a current through an auxillary secondary winding coupled to the primary winding and the secondary winding through a common core.

19. The device of claim 18 wherein the controller is powered from a low pass filter connected to the auxillary secondary winding.

20. The device of claim 16 wherein the surge protection module further comprises a remaining lifespan indicator and a surge voltage indicator.
